(19) United States
(12) Patent Application Publication
(10) Pub. No.: US 2025/0258967 A1
(43) Pub. Date: Aug. 14, 2025

(54) CLASH MARKER

(71) Applicant: Transparent Software, LLC, Odessa, FL (US)

(72) Inventors: Zachary Russell, Odessa, FL (US); David Russell, Odessa, FL (US)

(73) Assignee: Transparent Software, LLC, Odessa, FL (US)

(21) Appl. No.: 19/051,843

(22) Filed: Feb. 12, 2025

Related U.S. Application Data
(60) Provisional application No. 63/552,322, filed on Feb. 12, 2024.

(51) Int. Cl. G06F 30/12

(52) U.S. Cl. CPC G06F 30/12

(57) ABSTRACT

Embodiments for the invention provide a computer-implemented system and method to improve the functionality and performance of computer aided drawing (“CAD”) software.

### CROSS-REFERENCE TO RELATED APPLICATION(S)

The present application claims priority to U.S. Provisional Patent Application No. 63/552,322, entitled CLASH MARKER, filed on Feb. 12, 2024, the entirety of which is incorporated herein by reference.

### FIELD OF THE INVENTION

The present invention generally relates to computer-implemented systems and methods to improve the functionality and performance of computer aided drawing (“CAD”) software.

### BACKGROUND

There are many pieces of software systems that aim to improve upon base CAD software like AutoCAD™, BricsCAD™, SprinkCAD™, and Revit™, however there are none that accomplish the objectives described herein. The present improvements deal with “clash translation,” which is a process that involves marking clashes generated by a 3D design review product or a Clash Coordination tool (generated in a 3D Model) and translating those clashes into a much simpler 2D or 3D model that a user is working in. This marks the clash in the user's model with a specific instance which makes it much easier to locate the clash and resolve the clash. In an attempt to quicken this clash translation process, designers in the industry have developed different “hacks.” The best-known process designers use is the use of electronic spreadsheet programs, such as Microsoft Excel® templates. Specially crafted Excel® templates have been passed around online forums that allow designers to ease the process of translating clashes. None of these processes are similar to the present invention as they are not standalone systems and do not account for other details the present invention can account for. They simply aim to solve the hassle this specific process entails.

The present invention aims to solve the painstaking process of taking clash reports generated by a Coordination Software and translating those clashes onto a 2D or 3D model of a design plan that is produced by the user, or provided by a third party and given to the user to coordinate and provide the final design for coordination and installation. The industry currently does not have a uniform way of performing this process. Some designers do this process by hand, while others have found ways to use simple hacks to try and quicken the process. One of the common hacks is utilizing multiple specially crafted Excel® spreadsheets to quicken the process. None of the current ways of performing this process is as quick, efficient, and hands-off as the present invention.

The present invention solves this issue by completely automating the process many do by hand. By only requiring the user to supply the clash report XML files and additional optional input, the present invention automatically completes this process with no additional stress.

### SUMMARY OF THE INVENTION

Embodiments of the present invention address deficiencies of the art in respect to the functionality and performance of CAD software, and provide a novel and non-obvious computer-implemented method and system to improve such functionality and performance,

According to one or more embodiments, a computer implemented system for managing clashes in a computer aided design software comprises a data extraction plugin configured to extract clash report data and clash marker viewpoint report data, an interface configured to process the clash report data and the clash marker viewpoint report data; a translator module configured to interpret the clash report data and clash marker viewpoint report data, and a clash marker add-in configured to process the .cm Data. The translator module comprises a clash extraction module that comprises a data extraction module and a clash & viewpoint translation module. The data extraction module comprises a clash data extraction module and viewpoint data extraction module. The clash data extraction module is configured to extract viewpoint data. The clash & viewpoint translation module is configured to translate clash data and viewpoint data. The translator module further comprises a GUI control module configured to control the computer aided design software and a data export module configured to extract .cm Data. The clash marker add-in comprises a data import module and a family instance drawing module.

According to one or more embodiments, a method for managing clashes in a computer aided design system comprises extracting clash reports from the computer aided design system, converting the clash report into a normalized data report, and controlling the graphical user interface of a computer aided design system using the normalized data report.

In one aspect, the clash reports are extracted from a first computer aided design system and controlling the graphical user interface, controls the graphical user interface of a second computer aided design system.

In another aspect, converting the clash report further comprises rotating the data in

the normalized data report.

In another aspect, the data is rotated a pre-set angle.

In another aspect, the data is rotated at an angle inputted by a user.

In another aspect, extracting clash reports is performed by a stand-alone computer program.

In another aspect, extracting clash reports is performed by a plug-in interoperable with the computer aided design system.

In another aspect, controlling the graphical user interface comprises programmatically controlling a user input of the user interface.

In another aspect, the user input is a mouse.

In another aspect, the user input is a keyboard.

In another aspect, controlling the graphical user interfaces comprises generating instructions for the computer aided design system.

According to one or more embodiments, a computer implemented system for managing clashes in a computer aided design software comprises a clash extraction module and a clash & viewpoint translation module. The clash extraction module includes a data extraction module. The data extraction module includes a clash data extraction module configured to extract clash data and a viewpoint data extraction module configured to extract viewpoint data. The clash & viewpoint translation module is configured to translate clash data and viewpoint data.

In one aspect, the system further comprises a GUI control module configured to control the computer aided design software; and a data export module configured to extract .cm Data.

In another aspect, the system further comprises a clash marker add-in configured to process the .cm Data.

In another aspect, the clash marker add-in comprises a data import module; and a family instance drawing module.

In another aspect, the system further comprises a data extraction plugin configured to extract clash report data and clash marker viewpoint report data.

In another aspect, the system further comprises an interface configured to process the clash report data and the clash marker viewpoint report data.

In another aspect, the system further comprises a translator module configured to interpret the clash report data and clash marker viewpoint report data.

In another aspect, the translator module comprises the clash extraction module.

Additional aspects of the invention will be set forth in part in the description which follows, and in part will be obvious from the description, or may be learned by practice of the invention. The aspects of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute part of this specification, illustrate embodiments of the invention and together with the description, serve to explain the principles of the invention. The embodiments illustrated herein are presently preferred, it being understood, however, that the invention is not limited to the precise arrangement and instrumentalities shown, wherein:

FIG. 1 shows a clash translation system, in accordance with the principles of the present application;

FIG. 2 shows components of an exemplary clash translation system, in accordance with the principles of the present application;

FIG. 3 shows components of an exemplary clash translation system, in accordance with the principles of the present application;

FIG. 4 shows components of an exemplary clash translation system, in accordance with the principles of the present application;

FIG. 5 shows components of an exemplary clash translation system, in accordance with the principles of the present application;

FIGS. 6A-E show flowcharts demonstrating exemplary steps to be taken by components of an exemplary clash translation system, in accordance with the principles of the present application;

FIG. 7 shows an exemplary data format for a component of an exemplary clash translation system, in accordance with the principles of the present application;

FIG. 8 shows an exemplary screenshot for a component of an exemplary clash translation system, in accordance with the principles of the present application; and

FIGS. 9A-M show flowcharts demonstrating exemplary steps to be taken by components of an exemplary clash translation system, in accordance with the principles of the present application.

### DETAILED DESCRIPTION

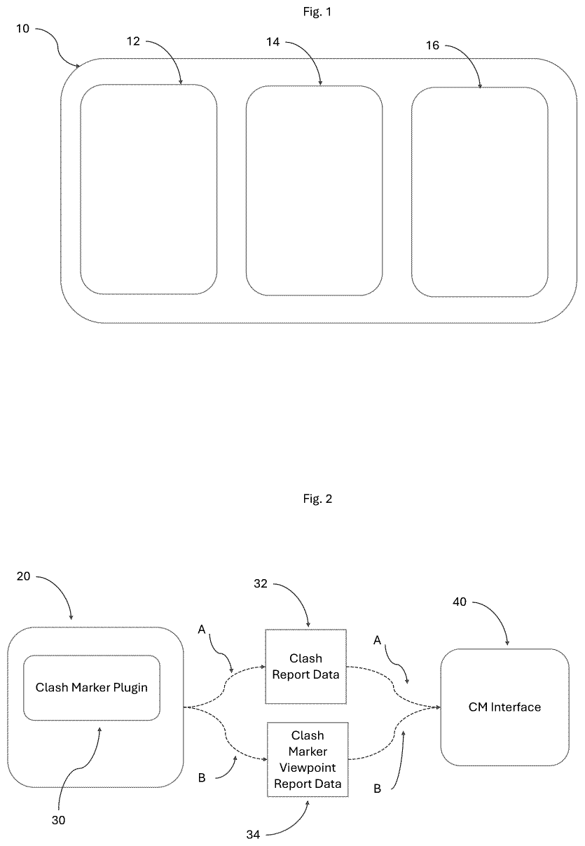

The present invention advantageously provides a system, and methods of use thereof, to improve the functionality and performance of clash resolution by programmatically unifying data between coordination software and computer aided drawing (“CAD”) software. Referring now to the drawing figures in which like reference designations refer to like elements, an exemplary of computer-implemented system constructed in accordance with principles of the present invention is shown in FIG. 1. As shown in FIG. 1, the system 10 comprises one or more computing devices configured to operate pursuant to this disclosure. In a preferred embodiment, the system 10 comprises a data extraction phase or component 12, a data handling component 14, and a data analysis or use component 16. Each of these components may comprise one or more computing devices configured to carry out the various system functions, operations, and processes necessary to facilitate the clash translation process described herein.

The one or more computing devices further include hardware and software configured to perform and execute the operations, functions, and processing necessary to implement the system described herein. In some embodiments, the hardware (HW) may include processing circuitry that comprises a processor and a memory in communication with the processor. In particular, in addition to or instead of a processor, such as a central processing unit and memory, the processing circuitry may include integrated circuitry for processing and/or control, e.g., one or more processors and/or processor cores and/or FPGAs (Field Programmable Gate Array) and/or ASIC's (Application Specific Integrated Circuitry) adapted or configured to execute instructions. The processor may be configured to access (e.g., to write to and/or read from) the memory, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory). Further, memory may be configured as a storage device.

The processing circuitry may be configured to control and of the methods and/or processes described herein and/or to cause such methods and/or processes to be performed by the computing device described herein. Processor corresponds to one or more processors for performing the computing device functions described herein. In some embodiments, the software may include instructions that, when executed by the processor and/or processing circuitry, cause the processor and/or processing circuitry to perform the processes described herein with respect to the computing device.

The software may be stored internally in, for example, memory, or stored in external memory (e.g., database, storage array, network storage device, etc.) and accessible via an external connection. The software may be executable by the processing circuitry.

Referring to FIG. 2, the system 10 utilizes multiple processes in order to perform its clash translation process. The system 10 interacts with coordination software 20 through Clash Marker plugin 30. Through this architecture, the data handling 14 and data analysis/use 16 components are separate from the coordination software 20, and the system 10 may easily interact with coordination software 20 provided by any number of vendors through the development of appropriate Clash Marker plugins 30. Coordination software 20 exports Clash Report Data 32 and/or Clash Marker Viewpoint Report Data 34 through Clash Marker Plugin 30. Clash Report Data 32 preferably comprises clash data from the model in the coordination software 20 and may include XYZ coordinates of the clash. Clash Marker Viewpoint Report Data 34 preferably comprises data from the model in the coordination software 20 relating to viewpoint information and may include viewpoint direction and associated clash.

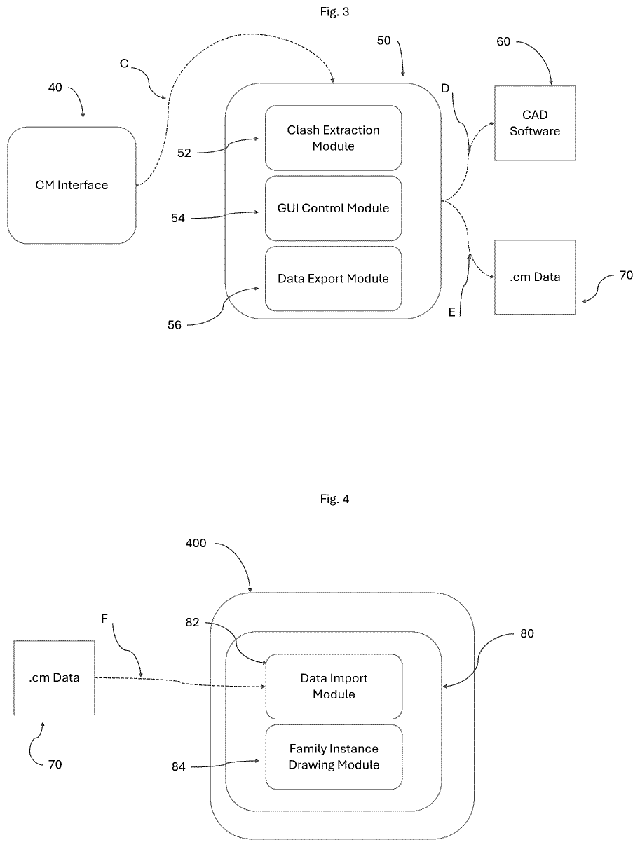

Data may be exported from coordination software in a number of ways. In one embodiment, data is exported using native tools of the coordination software. In other embodiments, data is exported using plugins (such as Clash Marker Plugin 30) or other software integrated into or with the coordination software. As shown in FIG. 2, Clash Report Data 32 is exported along pathway A, while Clash Marker Viewpoint Report Data 34 is exported along pathway B. These data are imported by the CM Interface 40. As described in FIG. 3., data from CM Interface is processed by the system 10 along pathway C. In a preferred embodiment, the system 10 comprises a Clash Translator 50 which itself comprises a Clash Extraction Module 52, a GUI Control Module 54, and a Data Export Module 56.

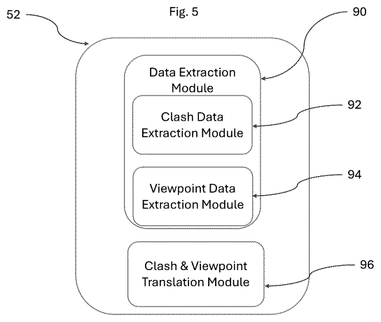

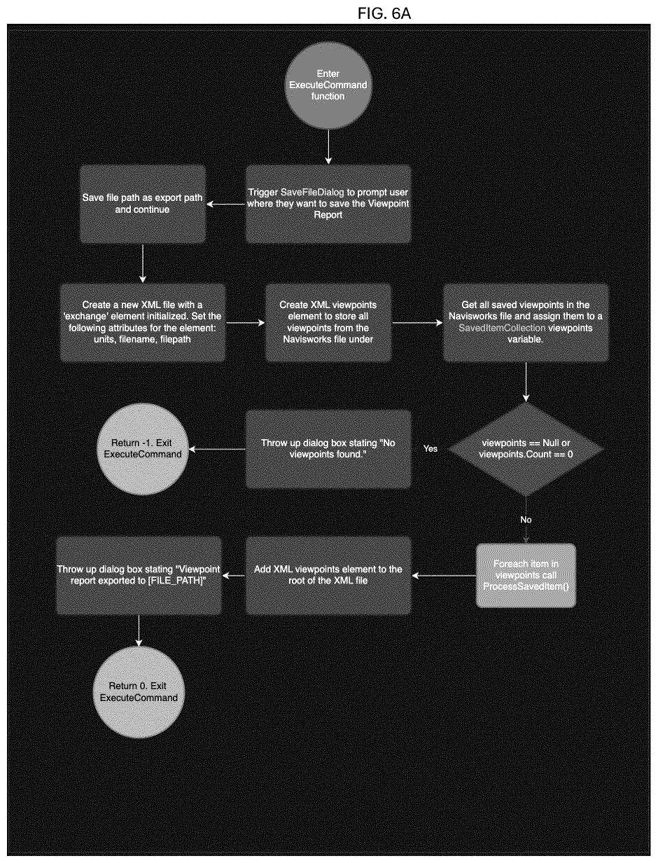

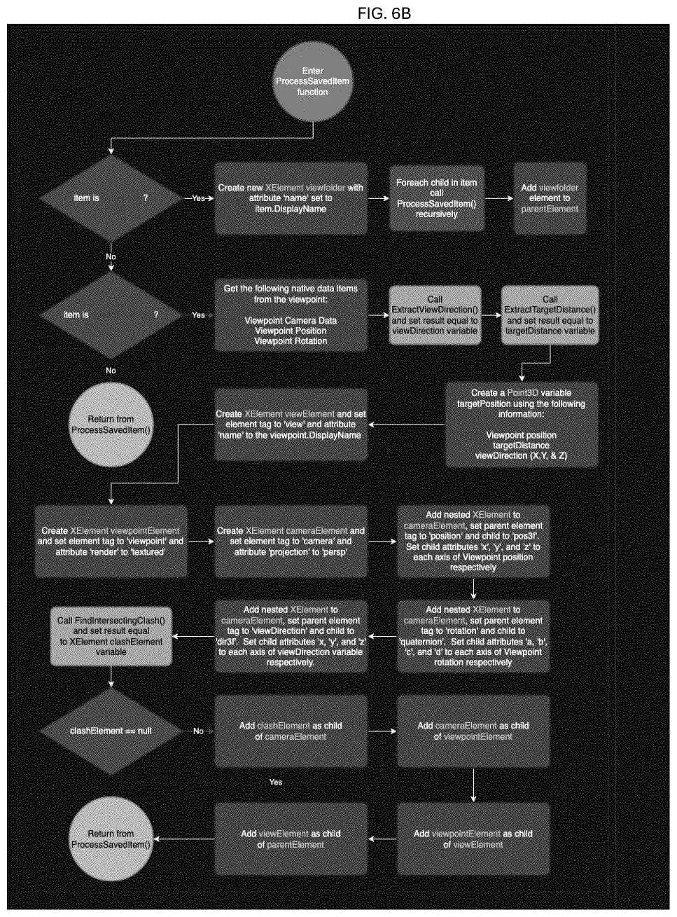

The Clash Extraction Module 52 is described in further detail in FIG. 5, and preferably comprises a Data Extraction Module 90 and a Clash & Viewpoint Translation Module 96. The Data Extraction Module 90 itself preferably comprises a Clash Data Extraction Module 92 and a Viewpoint Data Extraction Module 94. The Clash Extraction Module 52 preferably receives Clash Report Data 32 and Clash Marker Viewpoint Data 34 for processing. In a preferred embodiment, these data are structured data, such as XML data. The Data Extraction Module 90 is configured to process data from various coordination systems 20 so that it can provide the information necessary by this disclosure to perform the clash translation process described herein. For example, this extracted data may preferably include X, Y, Z coordinates, view direction, for example a vector3D, and a viewpoints respective clash as X, Y, Z coordinates.

The Clash & Viewpoint Translation Module 96 may also process the extracted coordinates in order to translate and rotate them based on the processing that is needed, if any. At the conclusion of this data extraction process, system 10 will either utilize GUI Control Module 54 or Data Export Module 56 to carry out the marking process in accordance with the present disclosure.

Returning to FIG. 3, the system 10 may then perform clash translation via alternative pathways. In one methodology, the GUI Control Module 54 is used in some instances to mark clashes on the CAD Software 60 via pathway D using simulated mouse movements and keystrokes. The system 10 may also use the Data Export Module 56 to convert Clash Report Data 32 and/or Clash Marker Viewpoint Report Data 34 into .cm Data 70 via pathway E. This .cm Data 70 is then used by the Clash Marker Add-in 80 as discussed below. In a preferred embodiment, .cm Data, which is exported by the Data Export Module 56, may include information relating to each clash or viewpoint. In a preferred embodiment, this data may be a line of information relating to each clash's or viewpoint's properties, such as their location, orientation, and ID number.

Turning to FIG. 4, .cm Data 70 is provided along pathway F to Clash Marker Add-in 80. Clash Marker Add-in 80 may preferably be integrated into other software 400. The Clash Marker Add-in 80 preferably comprises a Data Import Module 82 and Family Instance Drawing Module 84. The Data Import Module 82 is configured to interpret and process the .cm Data 70. The Family Instance Drawing Module 84 is configured to draw instances of families in accordance with the present disclosure.

Now that the system has been disclosed, further information on various embodiments of a system in accordance with the present disclosure is provided.

### Clash Marking Process

The system 10 may read XML file data provided by clash tests performed in a 3D design review product, such as the Naviswork product from Autodesk. In one embodiment, the necessary information needed for the present invention may be extracted from the XML file(s) using the following python regex:
r′“([\hat{ }″]*)′”

Alternatively, the core XML module in Python may be used. In one embodiment using Naviswork data, only the XYZ position of each clash is extracted from the XML file using built-in functions including .iter( ) and .findall( ). Each coordinate is stored together inside an array. Once all coordinates are extracted from the XML file, the coordinates are placed into pre-constructed commands that can be used across all platforms.

### Marking Clashes With Clash Marker in Non-GUI Based Software Like Revit

If the end user has selected Revit as their design suite, the clash translation module will generate the coordinates into commands that are assembled into a special file for the end user. This file, with the extension of .cm, is a Clash Marker Configuration file and contains the commands listed out that are later used by a Revit plug-in that is compatible with the present system. The structure of the command for a single clash inside a .cm Data 70 file is as described:
[CLASH ID #] [X COORD] [Y COORD] [Z COORD] [FAMILY NAME]

Where CLASH ID #is the number correlating to the ID number assigned to the clash by Navisworks, the X COORD, Y COORD, Z COORD encompass the XYZ position of the clash, and the FAMILY_NAME is the preset symbol chosen by the end user using the computing device. After all commands are written to the .cm Data 70, it is saved so that it can be imported by the Revit Plug-in to finish the marking process.

### Marking Clashes With Clash Marker in GUI-Based Software Like AutoCAD and BricsCAD

If the end user has selected AutoCAD or BricsCAD as their design suite, the commands are constructed with the following basic structure:
[BLOCK_NAME] [X COORD] [Y COORD] [Z COORD] [SCALE X] [SCALE Y] [ROTATION] [ANNOTATION #]

Where BLOCK_NAME is the preset symbol chosen by the end user in Clash Marker. X COORD, Y COORD, and Z COORD encompass the XYZ position of the clash. SCALE X, SCALE Y, and ROTATION(deg.) are used to alter the size and orientation of the symbol, and ANNOTATION # is the number correlating to the ID number assigned to the clash by Navisworks. This is an exemplary version of the command that excludes Autodesk keywords needed to insert an instance of the clash block. This demonstrates how the information extracted from the XML is laid out in the command without Autodesk's built-in commands.

### Building a Coordinate Array

The extracted information is the coordinates of the clashes found by the 3D design review product in an XYZ format. In a preferred embodiment, each coordinate is stored together inside an array. The coordinates are then placed into pre-constructed commands that can be used across all platforms. Depending upon prior selection in the program, the commands generated may be slightly different. For example, this difference can be seen in the positioning of the coordinates themselves. If a user's 3D coordination model is not located at the 0,0,0 origin point, they may enter a custom origin within the present invention. Thus, informing the present invention that all coordinates extracted from the XML file need to be shifted by the amount given by the user. The two types of commands are shown below:

Command with custom origin specified:

```
  commands.append(f”” (command “_-INSERT”
  “{cwd}/{fileBatch[file]}.dwg” “{float(coords[i][0]) −
  originX}’,{float(coords[i][1])−
originY}’,{float(coords[i][2]) −
  originZ}’” 1 1 100 {i+1} )”””)
```

Command without custom origin specified:

```
  commands.append(f””” (command “_-INSERT”
  “{cwd}/{fileBatch[file]}.dwg”
“{coords[i][0]}’,{coords[i][1]’,{coords[i][2]
  }’” 1 1 100 {i+1} )” ” ”)
```

In each command, there is a portion of the command that tells the CAD software what block to insert for the given clash. That portion of the command can be seen below:
“{cwd}/{fileBatch[file]}.dwg”

The present disclosure may also uses custom crafted structures for each type of clash designers may need. An exemplary list of structures currently available is below, but it is within the scope of this disclosure for any additional pre-constructed 2D or 3D structures to be utilized:
Chilled Water
Concrete
Duct
Electrical
Fire
Lights
Mechanical Pipe
Plumbing
PTube
Steel

For each coordinate extracted, they are each placed in a pre-constructed command string and then stored into a single array. Once all commands have been created with their necessary coordinates, they are all concatenated into a singular text string and copied to the computer's clipboard. With the necessary information extracted from the XML files and the completed commands copied onto the computer's clipboard, the present invention instructs the user to open their respective CAD file. Once the file is open, the user can click “Ok” in a dialog box and the present invention begins the next step of its process. Through this next part of the process, the present disclosure programmatically controls the computer system's mouse and keyboard so that the operator does not need to. This tool allows the present invention to programmatically control the computer's mouse and keyboard in order to perform the necessary actions to convert the copied commands into the CAD workspace. The following operations may be carried out by the present invention using an exemplary cross-platform GUI automation Python module, such as Py AutoGUI:
1. Using PyAutoGUI's locateCenterOnScreen function, Clash Marker locates the CAD software's command bar on the screen.
2. If found, Clash Marker programmatically clicks inside the command bar and proceeds to enter commands. The list of commands entered are as follows:
   a. Layer Creation
      i. —Layer
         1. Initiates the layer command flow in the CAD software
      ii. M
         1. Signifies that a new layer will be made
      iii. CLASH
         1. The name of the new layer to be created
   b. Workspace Configuration
      i. ATTDIA
         1. Used to configure the ATTDIA value which turns off/on dialog boxes when doing certain operations in CAD software.
      ii. 0
         1. This signifies that the ATTDIA value will be 0 meaning dialog boxes are turned off.
         i.

Once these commands are performed, the CAD workspace is configured for the commands created previously to be entered. With the command bar still in selection, the present invention programmatically uses the “ctrl-v” shortcut to paste the commands from the clipboard into the command bar.

### Revit Process:

In some embodiments, the present invention is adapted to work in a building information modelling (“BIM”) software, such as the Autodesk Revit™ software, that may be used by architects, engineers, designers, and contractors. Due to the nature of many BIM software being GUI-first programs, the present invention may be adapted to work differently with these types of software. For example, instead of programmatically controlling the user's screen to run commands like in the other CAD software, the present invention may instead generate an output file. The file generated by the present invention will likely be structured as follows:
[Clash ID #] [X Coordinate] [Y Coordinate] [Z Coordinate] [Clash Type]

This output file will then be used by an extension written using the API of the BIM software as disclosed above.

### Viewpoint Marking Process

### Extracting Viewpoint Data From Clash Marker Viewpoint Reports

The system 10 begins by analyzing the Clash Marker Viewpoint Report Data 34. Preferably, the Clash Marker Viewpoint Report Data 34 is XML data. The system 10 extracts the information needed which may include the viewpoint's XYZ position, the XYZ position of the clash associated with the viewpoint, and a Vector3 value called ViewDirection that describes the orientation of the viewpoint in a 3D space. In a preferred embodiment, all of this information is extracted from the XML file using built-in functions including .iter( ) and .findall( ).

Each piece of information extracted is stored separately in three different arrays. Once all information is extracted from the XML file, the pieces of information are placed into pre-constructed commands that can be used across all platforms as discussed above.

### Marking Viewpoints With Clash Marker in Non-GUI Based Software Like Revit

If an end user has selected Revit as their design suite, the clash translation module will generate the information into commands that are assembled into a special file for the end user in the same manner as described above. The structure of the command for a single viewpoint inside a .cm Data file 70 is as described:
[VIEWPOINTID #] [X VP COORD] [Y VP COORD] [Z VP COORD] [FAMILY NAME] [VIEWDIRECTION VECTOR 1] [VIEWDIRECTION VECTOR 2] [VIEWDIRECTION VECTOR 3] [XCLASH COORD] [Y CLASH COORD] [Z CLASH COORD]

Where VIEWPOINT ID # is the number correlating to the ID number assigned to the viewpoint by Navisworks. The X VP COORD, Y VP COORD, and Z VP COORD encompass the XYZ position of the viewpoint. FAMILY_NAME is the preset symbol chosen by the end user in VIEWDIRECTION VECTOR 1, VIEWDIRECTION VECTOR 2, and VIEWDIRECTION VECTOR 3, which are the three vectors that make up the orientation of the viewpoint in 3D space. The X CLASH COORD, Y CLASH COORD, and Z CLASH COORD encompass the XYZ position of the viewpoint's corresponding clash. After all commands are written to the .cm Data 70, it is saved so that it can be imported by the Revit Plug-in to finish the marking process.

### Marking Viewpoints With Clash Marker in GUI-Based Software Like AutoCAD and BricsCAD

If the end user has selected AutoCAD or BricsCAD as their design suite, the commands for inserting the viewpoint blocks and the clash blocks are constructed with the same following structure:
[BLOCK NAME] [X COORD] [Y COORD] [Z COORD] [SCALE X] [SCALE Y] [ROTATION] [ANNOTATION #]

Where BLOCK_NAME is the preset symbol chosen by the end user in Clash Marker. X COORD, Y COORD, and Z COORD encompass the XYZ position of the clash. SCALE X, SCALE Y, and ROTATION(deg.) are used to alter the size and orientation of the symbol, and ANNOTATION # is the number correlating to the id number assigned to the clash by Navisworks.

### Building a Coordinate Array

First, one array is used to store the ViewDirection values of each viewpoint. Then, since both the viewpoint location is being marked and the clash associated with the viewpoint is being marked, the clash translation module uses two separate arrays each with their own list of commands; one array contains the commands for inserting the viewpoint blocks, and the other for inserting the clash blocks. The ViewDirection array is used when creating the viewpoint block commands in order to calculate the amount the block must be rotated for it to face in the direction of the clash. The math process used to calculate the rotation needed is described below:

$$( 1 ) Δ X = X Coord of Clash ( ft . ) - X Coord of Viewpoint ( ft . )$$

$$( 2 ) Δ Y = Y Coord of Clash ( ft . ) - Y Coord of Viewpoint ( ft . )$$

$$( 3 ) Angle ( deg . ) = ( {tan}^{- 1} ( \frac{Δ Y}{Δ X} ) ) * \frac{180}{π}$$

The angle returned from this process is inserted in the ROTATION field of the viewpoint command structure previously described. Once all commands have been created with their necessary information, both arrays of commands are concatenated into a singular text string and copied to the computer's clipboard. The string is built so that a viewpoint block insertion command is coupled its respective clash block insertion command. With the necessary information extracted from the XML files and the completed commands copied onto the computer's clipboard, Clash Marker instructs the end user to open their respective CAD file. Once the file is open, the end user can click “Ok” in a dialog box and Clash Marker begins the next step of its process. This portion of the present system relies heavily on the operations carried out by the PyAutoGUItool, previously discussed.

### Custom Transform and Rotation Handling for Clashes

In some cases, the end user's model will be transformed away from the 0,0,0 origin, or rotated about the origin; however, the end user's CAD file or model is located at the 0,0,0 origin. This translation can be done on either clashes or viewpoints. The clash translation module supports these custom transforms by altering the XYZ position of the clashes as they are read in from the XML file. For custom transforms, the end user can enter the XYZ transforms into the computing device in feet and inches. Using the values the end user entered, each clash XYZ location is subtracted by the transform amount entered converted into feet (i.e., 1′7″=1.583′). The formulas for calculating the new XYZ location is as follows:

New X=Old X (ft.)−X Transform Value (ft.)

New Y=Old Y (ft.)−Y Transform Value (ft.)

New Z=Old Z (ft.)−Z Transform Value (ft.)

For a custom rotation, the end user can enter the rotation transform value into the computing device in degrees. Using the rotation value, each clash XY location components is re-calculated using a series of trigonometric functions combined with simple math. The Z component of the location does not need to be altered. The process for calculating the new XY location components for each clash is as follows:

New X=Old X (ft.)*cos(Rotation (deg.))−Old Y (ft.)*sin(Rotation(deg.))

New Y=Old X (ft.)*sin(Rotation (deg.))+Old Y (ft.)*cos(Rotation(deg.))

For clarity, it's important to note these transforms are applied to the XYZ locations before the clashes are inserted into the pre-constructed commands for all supported design software.

According to one or more alternative embodiments, if the user previously signified that their model is rotated at a specific angle about the 0, 0, 0 center point, the present invention programmatically performs this rotation. To do this, the following LISP command may be entered into the command bar:

```
(defun c:sel ( )
    (sssetfirst nil (ssget “X” (list (cons 8 (getvar
“clayer”)))))
    (princ)
  ) ; end defun
```

The LISP command is necessary because it allows the present invention to alter the “SEL” CAD command to select everything located on a single layer instead of needing to use the mouse to create a selection area. Once the LISP command is processed the following commands may be entered by a user to perform the rotation:

### Layer Rotation

a. SEL
   i. Selects all of the items on the current layer
b. ROTATE
   i. Signifies that the current selection is being rotated
c. Rotation Coordinates
   i. The rotation angle specification is entered into the command bar.

This completes the process the present invention performs in order to take clash report XML files from a 3D coordination software and use them to generate and draw clash markers onto a 2D CAD file. However, it is to be understood that any 3D design review product that allows users to open and combine 3D models, navigate around the models in real-time, and review the models using a set of tools including comments, viewpoint, redlining, and measurements may be used.

### Viewpoint Notes Generated by Clash Marker

After the clash translation module inserts the viewpoints into the end user's CAD model, or generates the .cm Data 70, a text file may also be generated containing an organized list of the names of each of the viewpoints with the associated number. The names of the viewpoints often detail what the coordinator wants the designer to do with the current clash the viewpoint is looking at. This organized list allows the end user to have a complete file full of the instructions for each viewpoint next to the # that was assigned to it by the clash translation module. An example line of this file is may be per below:
[VIEWPOINT #]: [COMMENT]

### Clash Marker Plug-Ins

As disclosed above, the system 10 preferably may include one or more plug-ins for various software platforms. The below disclosures discusses some information concerning some preferred embodiments.

### Clash Marker Navisworks Plug-In

The Navisworks plug-in for the present system may add a single tool to the Navisworks software. This tool's function is to export a more detailed viewpoint report than the native one Navisworks offers. For the clash translation module to correctly display viewpoints on end user's BIM/CAD software, more information is needed from Navisworks about the properties of the viewpoint in the model. With these extra details, the clash translation module can accurately mark viewpoints and their corresponding clashes in the end user's BIM/CAD software.

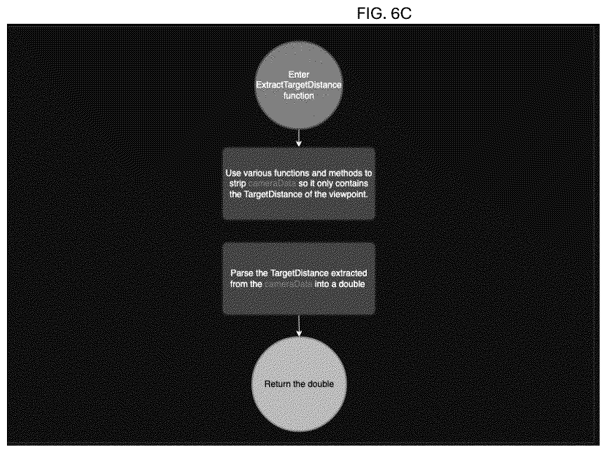

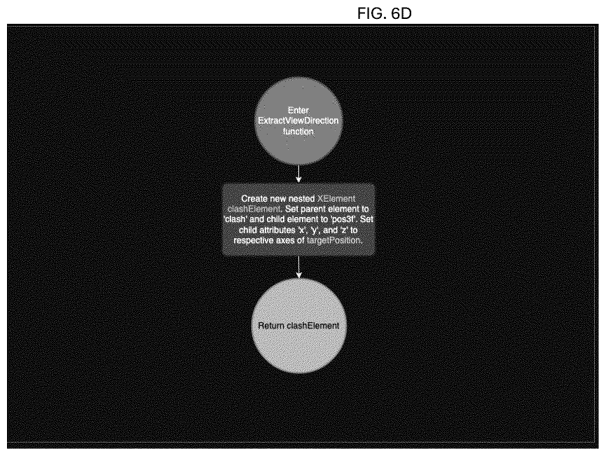

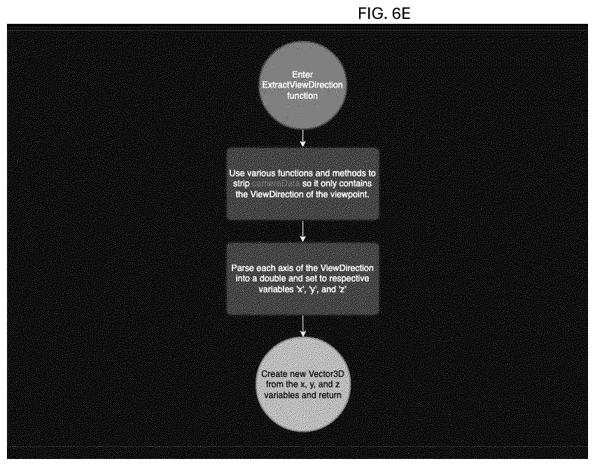

As shown in FIG. 6A-6E, the Navisworks plug-in works by first requesting the end user select a place to save the viewpoint report and specifying a name for the file. Once a file name is chosen and the path for the file to be saved at is selected, the plug-in constructs the viewpoint report in an XML format. All the saved viewpoints in the Navisworks file are iterated through using a loop and passed to the ProcessSavedItem function.

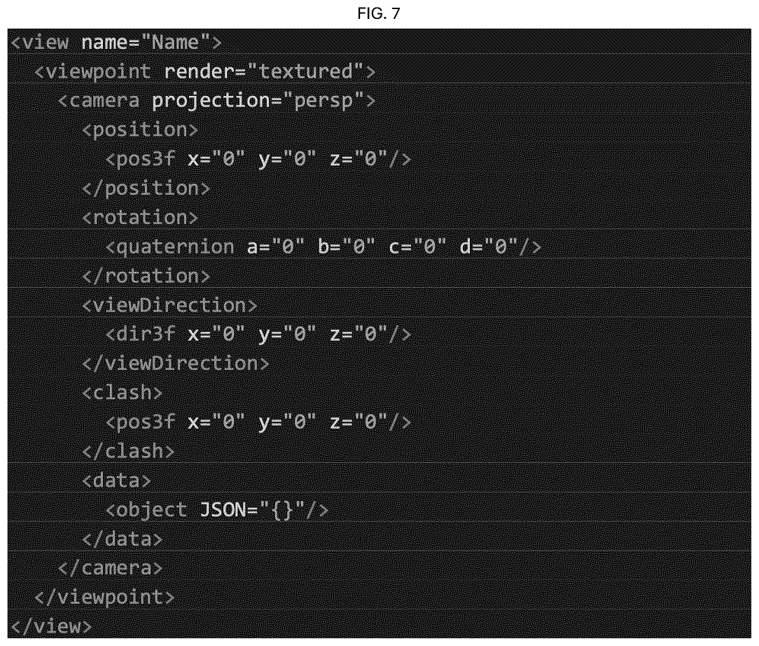

As shown in FIG. 6B, in the ProcessSavedItem function, first the saved item is evaluated to see if it is a viewpoint folder, if it is, the function is called recursively until a singular viewpoint object is found. This effectively evaluates the saved viewpoints within the viewpoint folder and any sub folders it may have. All viewpoints found within a viewpoint folder are nested within an XML tag labeled viewfolder. If the saved item is a singular viewpoint object an XML tag labeled view is created and the detailed XML tags are created inside of it. An exemplary XML format of a singular viewpoint inside the file is as shown in FIG. 7.

This XML contains similar information to the one natively produced by Navisworks, but it strips any unwanted information from the report and adds information about the Navisworks model that isn't usually included in the native viewpoint report. The additional information extracted includes fields like the viewpoint view Direction, the clash position (which is actually described as the target position of the viewpoint), and the data field (which contains general information about the viewpoint camera's properties). Once the plug-in has finished iterating through all of the saved viewpoints in the Navisworks model, the XML file is finalized and saved to the directory previously picked out by the end user.

As shown in FIGS. 6C and 6D, this exemplary plugin also includes functionality to extract target distances and extract view directions.

### Clash Marker Revit Plug-In

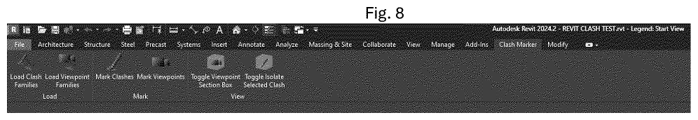

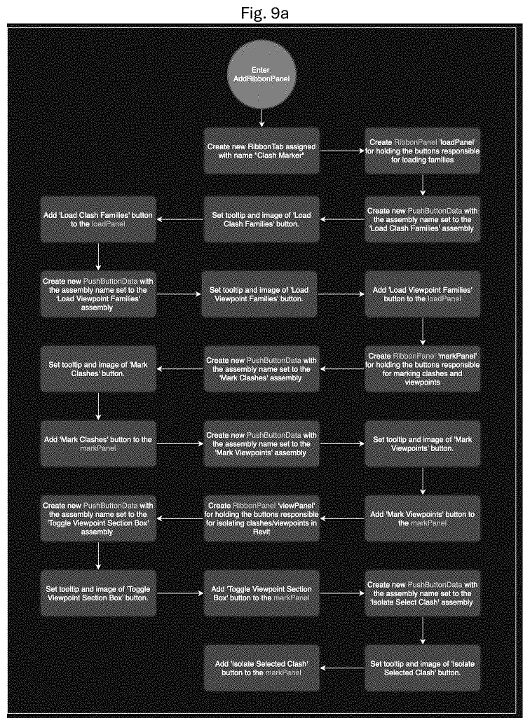

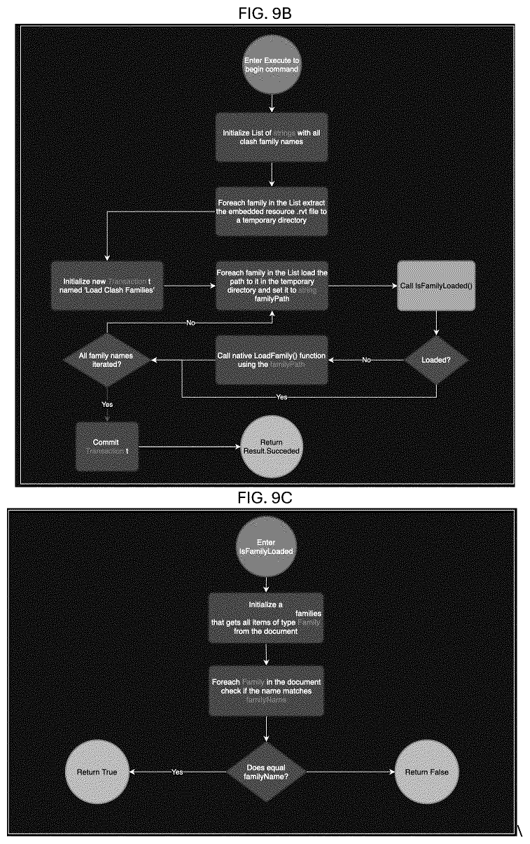

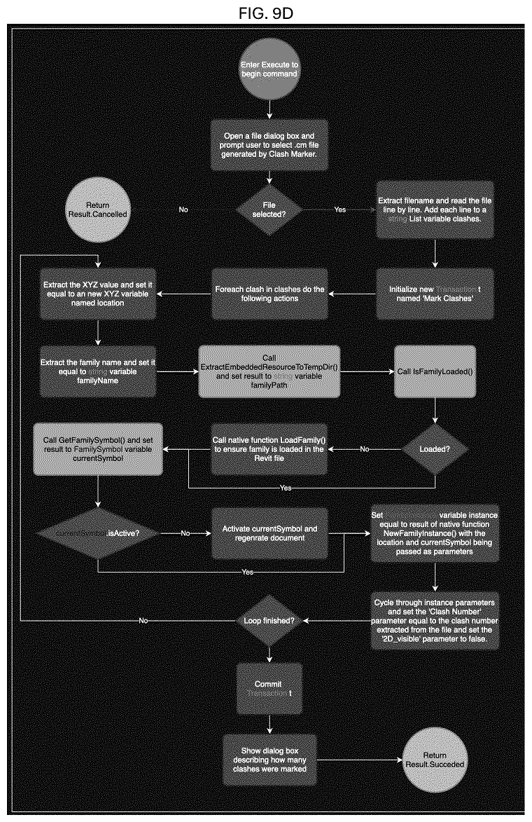

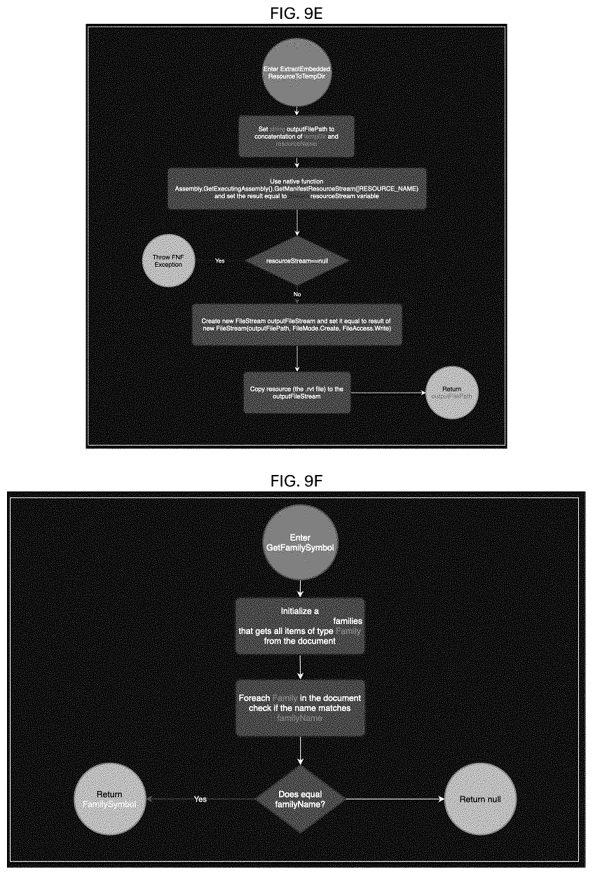

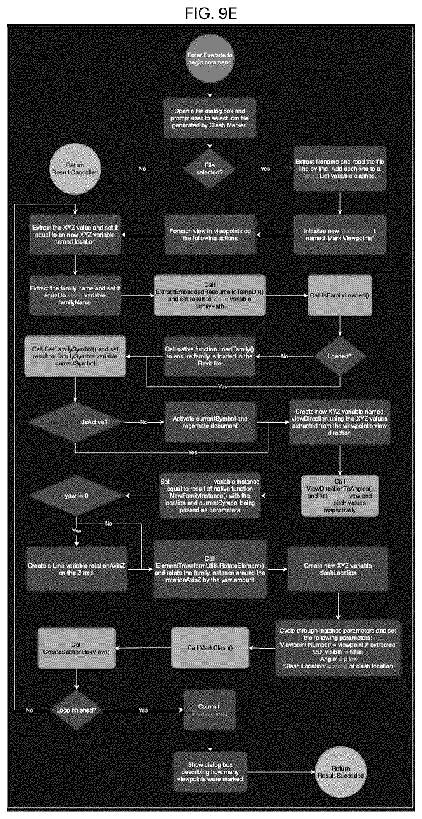

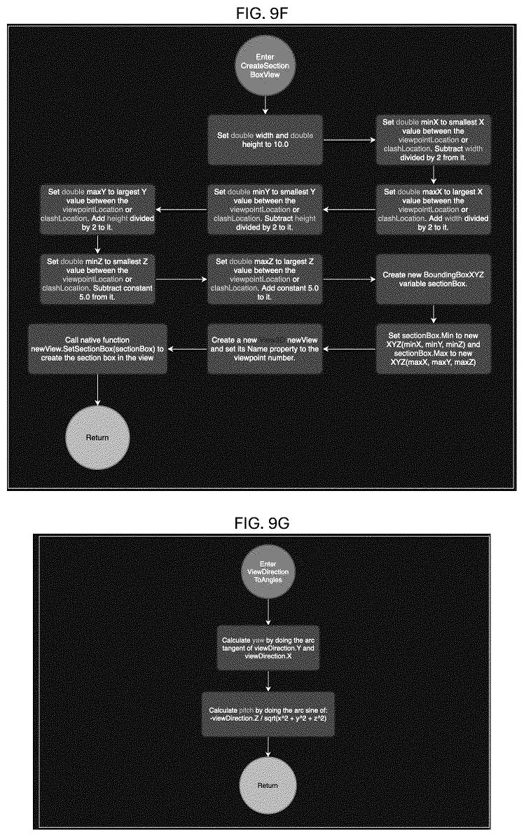

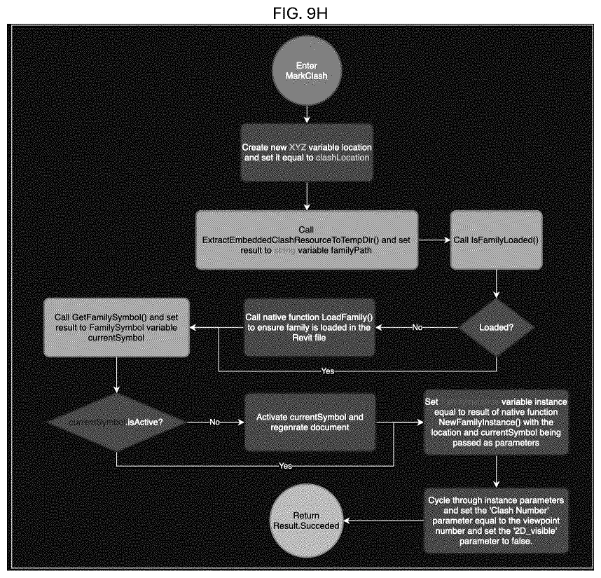

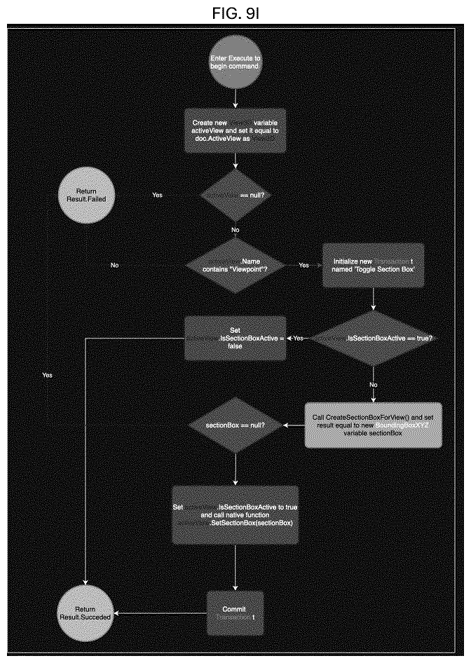

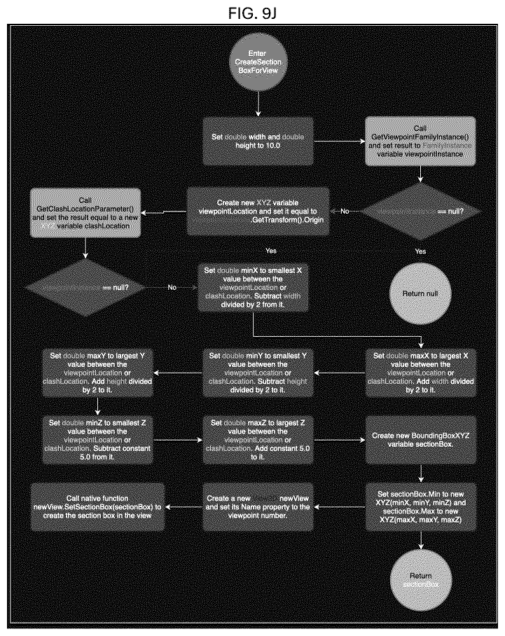

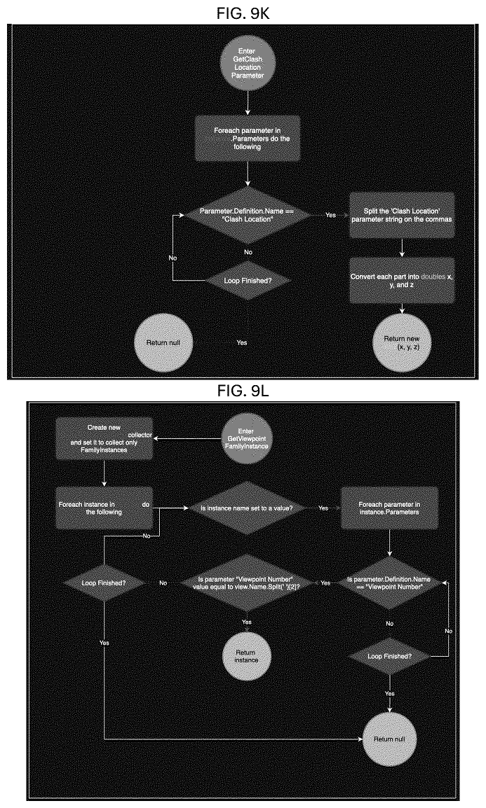

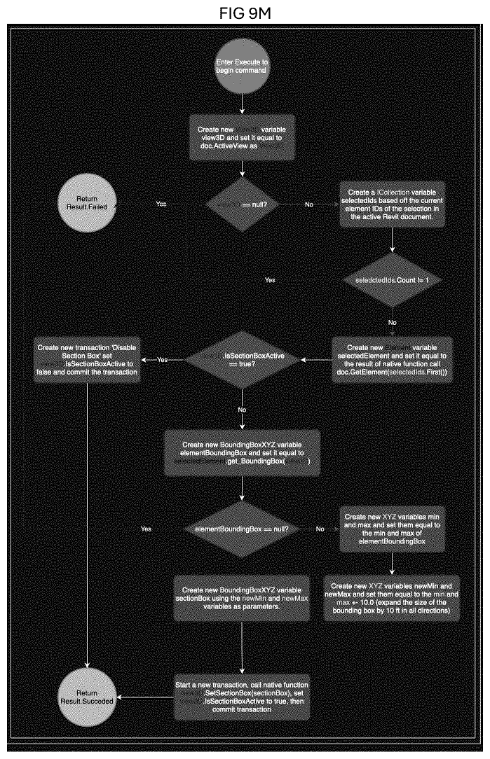

An exemplary screen showing a plugin in accordance with the present disclosure for the Revit system is shown in FIG. 8. A number of buttons are demonstrated through this embodiment, including Load Clash Families, Load Viewpoint Families, Mark Clashes, Mark Viewpoints, Toggle Viewpoint Section Box, and Toggle Isolate Selected Clash. It is to be understood, and within the scope of this invention, to include some, all, or none of these buttons, as well as other buttons. FIGS. 9A-9M provide flow charts for the various process executed by the Revit plugin in a preferred embodiment.

FIG. 9A discloses a process for adding a ribbon such as shown in FIG. 8 to the plugin. FIG. 9B discloses a flowchart for loading a clash family or a viewpoint family. Thus, for example, when a user clicks the Load Clash Families button shown on FIG. 8, in a preferred embodiment, a C # class executes a transaction to load the Clash Marker clash families into a Revit project using the Revit API. This C # class extracts the Revit Clash Marker clash families that are embedded resources in the code and loads them in the current Revit model. This helps speed up the clash/viewpoint marking process. If the families are not pre-loaded into the model they are instead loaded while they are being marked, which can slow down the marking process.

Similarly, if a user clicks the Load Viewpoint Families button, in a preferred embodiment a C # class executes a transaction to load the Clash Marker viewpoint families into a Revit project using the Revit API. This C # class extracts the Revit Clash Marker viewpoint families that are embedded resources in the code and loads them in the current Revit model. This helps speed up the clash/viewpoint marking process. If the families are not pre-loaded into the model they are instead loaded while they are being marked, which can slow down the marking process.

For either loading clash families or loading viewpoint families, in a preferred embodiment the process will also utilize the functionality disclosed in FIG. 9C for determining whether or not the family has been loaded.

When the user clicks the Mark Clashes button, a process as disclosed in FIG. 9D is preferably performed. In a preferred embodiment, the process runs a C # class that executes a transaction to mark clash points from an input file on a Revit model using the Revit API. The class first opens a file dialog box within Revit so the user can select the .cm file that they should've already generated using Clash Marker. Once selected, the file is read line by line and added to a List of string arrays. The List is then iterated through using a loop to insert each clash. The process for inserting each individual clash is as follows: the coordinates from the .cm file are made into an XYZ variable, and the family name is saved to a variable as well. A process for extracting the family path is disclosed in FIG. 9E. The clash family is loaded (if not already done) and then activated if it isn't already. The process preferably uses the same logic above as described in FIG. 9C for determining whether a family is loaded. A new instance of the family is created at the XYZ location extracted and the Clash Number parameter in the specific family instance is set to the id number from the .cm file. A process for getting the family symbol is disclosed in FIG. 9F. Once the loop is completed a dialog box pops up detailing to the user how many clashes were marked in the document.

When the user clicks the Mark Viewpoints button, a process as disclosed in FIG. 9E is preferably performed, and preferably runs a C # class that executes a transaction to mark viewpoints and their corresponding clash points from an input file on a Revit model using the Revit API. The class first opens a file dialog box within Revit so the user can select the .cm file that they should've already generated using the clash translation module. Once selected, the file is read line by line and added to a List of string arrays. The List is then iterated through using a loop to insert each viewpoint and corresponding clash. The process for inserting each individual clash is as follows: The coordinates from the .cm file are made into an XYZ variable, and the family name is saved to a variable as well. The viewpoint family is loaded (if not already done) and then activated if it isn't already. The view direction vectors are extracted from the input file and used to calculate the rotation of the viewpoint. The mathematical processes for converting the 3 vectors into yaw and pitch angles is as follows:

$$\begin{matrix}yaw = arctan ( yaw = arctan ( \frac{Y View Direction}{X View Direction} ) \\ pitch = arcsin ( \frac{- Z View Direction}{\sqrt{{x}^{2} + {y}^{2} + {z}^{2}}} )\end{matrix}$$

Once the pitch and yaw are calculated, anew instance of the family is created at the XYZ location extracted from the .cm file. If the yaw is not 0, the viewpoint family instance is rotated the calculated number of degrees. In the viewpoint family instance's properties, the Angle parameter (which controls the pitch of the family) is set equal to the calculate pitch, the Viewpoint Number parameter is set equal to the id number from the .cm file, and the Clash Location parameter is set equal to a string describing the XYZ location of the viewpoints corresponding clash. Once the viewpoint has been successfully marked, its corresponding clash is marked using the same process described previously in the ‘Mark Clashes’ C # class.

The last thing done for each viewpoint is the process of making an individual 3D view. In Revit, you can make multiple different 3D views that allow you to look at the model in different manners. For each viewpoint marked on the Revit model, a 3D view is made with a section box measuring 10 ft×10 ft×5 ft around it. This section box hides all other parts of the model and allows the end user to view just the viewpoint and its clash in an isolated view. Once the loop is completed a dialog box opens detailing to the user how many viewpoints were marked in the document. These steps are shown in an exemplary embodiment in FIGS. 9F-H.

As shown in FIGS. 9I-9L, executing the toggle viewpoint section box button runs a C # class that executes a transaction to toggle the section box inside its custom 3D view either on or off using the Revit API. The class first makes sure that both a 3D view is open and the 3D view is one of the custom 3D views Clash Marker creates when marking viewpoints. Then the class checks whether a section box is already active, if it is, it is toggled off so the end user can see their entire Revit model. If it is not active, the section box is re-created around the viewpoint correlating to the ID number in the name of the custom 3D view. The section box is re-made the same size as when it was originally created, 10 ft×10 ft×5 ft. This button can be used to toggle the section box around the viewpoint on and off indefinitely.

As shown in FIG. 9M, pressing the Isolate Selected Clash button runs a C # class that executes a transaction to toggle a section box around a selected item in the Revit model. Although the button is labeled ‘Isolate Selected Clash’ the functionality of this button can be used for ANY selected item in the Revit model, even items that weren't created by Clash Marker. The class first makes sure that a 3D view is open, and a single element is selected in it. If a section box is already active in the 3D view, then it is toggled off so the end user can see the rest of their model. If a section box is not already active, the bounding box around the selected item is fetched. Then using the bounding box around the selected item, a preset value of 10 ft×10 ft×10 ft is added to all axes of the bounding box to determine the size of the section box. The section box is then created around the selected item. This button can be used to toggle the section box on and off indefinitely around the selected item.

It should be understood that various aspects disclosed herein may be combined in different combinations than the combinations specifically presented in the description and accompanying drawings. It should also be understood that, depending on the example, certain acts or events of any of the processes or methods described herein may be performed in a different sequence, may be added, merged, or left out altogether (e.g., all described acts or events may not be necessary to carry out the techniques). In addition, while certain aspects of this disclosure are described as being performed by a single module or unit for purposes of clarity, it should be understood that the techniques of this disclosure may be performed by a combination of units or modules.

In one or more examples, the described techniques may be implemented in hardware, software, firmware, or any combination thereof. If implemented in software, the functions may be stored as one or more instructions or code on a computer-readable medium and executed by a hardware-based processing unit. Computer-readable media may include non-transitory computer-readable media, which corresponds to a tangible medium such as data storage media (e.g., RAM, ROM, EEPROM, flash memory, or any other medium that can be used to store desired program code in the form of instructions or data structures and that can be accessed by a computer).

Instructions may be executed by one or more processors, such as one or more digital signal processors (DSPs), general purpose microprocessors, application specific integrated circuits (ASICs), field programmable logic arrays (FPGAs), or other equivalent integrated or discrete logic circuitry. Accordingly, the term “processor” as used herein may refer to any of the foregoing structure or any other physical structure suitable for implementation of the described techniques. Also, the techniques could be fully implemented in one or more circuits or logic elements.

It will be appreciated by persons skilled in the art that the present invention is not limited to what has been particularly shown and described herein above. In addition, unless mention was made above to the contrary, it should be noted that all of the accompanying drawings are not to scale. A variety of modifications and variations are possible in light of the above teachings without departing from the scope and spirit of the invention, which is limited only by the following claims.

What is claimed is:

1. A computer implemented system for managing clashes in a computer aided design software, the system comprising:
a data extraction plugin configured to extract clash report data and clash marker viewpoint report data;
an interface configured to process the clash report data and the clash marker viewpoint report data;
a translator module configured to interpret the clash report data and clash marker viewpoint report data, wherein the translator module comprises:
a clash extraction module, comprising:
a data extraction module and a clash & viewpoint translation module,
the data extraction module comprising a clash data extraction module and viewpoint data extraction module, wherein the clash data extraction module is configured to extract clash data and the viewpoint data extraction module is configured to extract viewpoint data;
the clash & viewpoint translation module configured to translate clash data and viewpoint data;
a GUI control module configured to control the computer aided design software; and
a data export module configured to extract .cm Data;
a clash marker add-in, wherein the clash marker add-in is configured to process the .cm Data, wherein the clash marker add-in comprises:
a data import module; and
a family instance drawing module.

2. A method for managing clashes in a coordination software system, the method comprising:
extracting clash reports from the coordination software system;
converting the clash report into a normalized data report; and
controlling the graphical user interface of a computer aided design system using the normalized data report.

3. The method of claim 2, wherein the clash reports are extracted from a first coordination software system and controlling the graphical user interface, controls the graphical user interface of a second computer aided design system.

4. The method of claim 2, wherein converting the clash report further comprises:
rotating the data in the normalized data report.

5. The method of claim 4, wherein the data is rotated a pre-set angle.

6. The method of claim 2, wherein converting the clash report further comprises:
translating the data in the normalized data report.

7. The method of claim 2, wherein extracting clash reports is performed by a stand-alone computer program.

8. The method of claim 2, wherein extracting clash reports is performed by a plug-in interoperable with the computer aided design system.

9. The method of claim 2, wherein controlling the graphical user interface comprises programmatically controlling a user input of the user interface.

10. The method of claim 9, wherein the user input is a mouse.

11. The method of claim 9, wherein the user input is a keyboard.

12. The method of claim 2, wherein controlling the graphical user interface comprises generating instructions for the computer aided design system.

13. A computer implemented system for managing clashes in a computer aided design software, the system comprising:
a clash extraction module, the clash extraction module including:
a data extraction module, the data extraction module including:
a clash data extraction module configured to extract clash data; and
viewpoint data extraction module configured to extract viewpoint data; and
a clash & viewpoint translation module configured to translate clash data and viewpoint data.

14. The system of claim 13, further comprising:
a GUI control module configured to control the computer aided design software; and
a data export module configured to extract .cm Data.

15. The system of claim 14, further comprising:
a clash marker add-in configured to process the .cm Data.

16. The module of claim 14, wherein the clash marker add-in comprises:
a data import module; and
a family instance drawing module.

17. The system of claim 15, further comprising a data extraction plugin configured to extract clash report data and clash marker viewpoint report data.

18. The system of claim 17, further comprising an interface configured to process the clash report data and the clash marker viewpoint report data.

19. The system of claim 18, further comprising a translator module configured to interpret the clash report data and clash marker viewpoint report data.

20. The system of claim 19, wherein the translator module comprises the clash extraction module, the GUI control module, and the data export module.
